(19) United States
(12) Patent Application Publication
(10) Pub. No.: US 2021/0153363 A1
(43) Pub. Date: May 20, 2021

(54) SUPPORTING STRUCTURE AND DISPLAY DEVICE

(71) Applicant: BOE TECHNOLOGY GROUP CO., LTD., Beijing (CN)

(72) Inventors: Fangxu CAO, Beijing (CN); Haoran WANG, Beijing (CN); Liming DONG, Beijing (CN); Yonghong ZHOU, Beijing (CN); Paoming TSAI, Beijing (CN); Xueyang CAO, Beijing (CN)

(21) Appl. No.: 16/822,299

(22) Filed: Mar. 18, 2020

(30) Foreign Application Priority Data
Nov. 15, 2019 (CN) 201911117203.8

(51) Int. Cl. H05K 5/00

(52) U.S. Cl. CPC H05K 5/0017; H01L 51/0097

(57) ABSTRACT

A supporting structure is described that may be applied to a flexible display panel and a display device. A flexible display panel includes a bendable region, where a bending axis corresponds to the bendable region extends in a first direction. The supporting structure includes a hollowed-out region, which has an orthographic projection on the flexible display panel completely covering the bendable region. The hollowed-out region includes a first portion having a plurality of first hollowed-out holes, and at least two second portions located at opposite sides of the first portion in the first direction and having a plurality of second hollowed-out holes. A ratio between a total area of the plurality of second hollowed-out holes and a total area of the at least two second portions is different from a ratio between a total area of the plurality of first hollowed-out holes and a total area of the first portion.

### CROSS-REFERENCE TO RELATED APPLICATION

This application is based on and claims the benefit of and priority to Chinese Patent Application No. 201911117203.8, filed on Nov. 15, 2019, where the entire contents of which are incorporated herein by reference.

### TECHNICAL FIELD

The present disclosure relates to the field of display technologies and, in particular, to a supporting structure and a display device.

### BACKGROUND

With the development of display technologies, flexible display panels that can be folded, stretched, curled, or the like are gradually increasing in the market. In order to facilitate bending or restoration of flexible display panels, it is necessary to make the flexible display panel thinner and lighter.

However, as flexible display panels become thinner and lighter, the overall bending resistance and impact resistance are lessened, and the reliability and stability of various products are reduced.

It should be noted that the information disclosed in the above “Background” section is only intended to enhance understanding of the background of the present disclosure, and thus may include information that does not constitute the prior art as already known by an ordinary person skilled in the art.

### SUMMARY

An objective of the present disclosure is to provide a supporting structure and a display device that ensures structural stability of the supporting structure and enhances impact resistance and bending resistance of the flexible display panel.

The present disclosure provides a supporting structure applied to a flexible display panel. The flexible display panel includes a bendable region, and a bending axis corresponding to the bendable region extends in a first direction. The supporting structure includes a hollowed-out region, and an orthographic projection of the hollowed-out region on the flexible display panel completely covers a region of the flexible display panel where the bendable region is located. The hollowed-out region includes a first portion having a plurality of first hollowed-out holes and at least two second portions at opposite sides of the first portion in the first direction, where each has a plurality of second hollowed-out holes. A ratio between a total area of the plurality of second hollowed-out holes and a total area of the at least two second portions is different from a ratio between a total area of the plurality of first hollowed-out holes and a total area of the first portion.

In one or more exemplary embodiments of the present disclosure, the first hollowed-out holes are obround holes extending in the first direction. The plurality of first hollowed-out holes are arranged in an array, and the first hollowed-out holes adjacent to each other in a second direction are staggered. The second direction is orthogonal to the first direction.

In one or more exemplary embodiments of the present disclosure, a size of the first hollowed-out hole in the first direction is A, an interval between the first hollowed-out holes adjacent to each other in the second direction is C, and a bending radius corresponding to the supporting structure is R, where

$$\frac{{C}^{3}}{{A}^{3}} < 4.5 \times R .$$

In one or more exemplary embodiments of the present disclosure, an interval between the first hollowed-out holes adjacent to each other in the first direction is B, a size of the first hollowed-out hole in the second direction is D, and a size of the first hollowed-out hole in its axial direction is E, where a ratio between A and B is 10 to 100, a ratio between B and C is 0.5 to 4, a ratio between D and C is 1 to 5, and a ratio between E and C is 1 to 4.

In one or more exemplary embodiments of the present disclosure, the first portion and each of the at least two second portions are symmetrically disposed with respect to the bending axis. The ratio between the total area of the plurality of second hollowed-out holes and the total area of the at least two second portions is greater than the ratio between the total area of the plurality of first hollowed-out holes and the total area of the first portion.

In one or more exemplary embodiments of the present disclosure, in a direction from a center of the first portion to either of the at least two second portions, a size of the first portion in the second direction is unchanged, and a size of either of the at least two second portions in the second direction gradually increases. A minimum size of either of the at least two second portions in the second direction is greater than or equal to the size of the first portion in the second direction.

In one or more exemplary embodiments of the present disclosure, in a direction from the center of the first portion to either of the at least two second portion, a size of the first portion in the second direction gradually increases, and a size of either of the at least two second portion in the second direction gradually increases. A minimum size of either of the at least two second portion in the second direction is greater than or equal to a maximum size of the first portion in the second direction.

In one or more exemplary embodiments of the present disclosure, an area of the second hollowed-out holes is larger than an area of the first hollowed-out holes.

In one or more exemplary embodiments of the present disclosure, the second hollowed-out holes are obround holes extending in the first direction. The plurality of second hollowed-out holes are arranged in an array, and second hollowed-out holes adjacent to each other in the second direction are staggered. A size of the second hollowed-out hole in the first direction is larger than a size of the first hollowed-out hole in the first direction; and/or a size of the second hollowed-out hole in the second direction is larger than a size of the first hollowed-out hole in the second direction.

In one or more exemplary embodiments of the present disclosure, the first hollowed-out hole has a first body portion and first end portions located at opposite sides of the first body portion in the first direction. The second hollowed-out hole has a second body portion and second end portions located at opposite sides of the second body portion in the first direction. An area and a shape of the first body portion are identical to an area and a shape of the second body portion, and the first end portion is different from the second end portion in the shape, and an area of the second end portion is larger than an area of the first end portion.

In one or more exemplary embodiments of the present disclosure, an area and a shape of the second hollowed-out hole are identical to an area and a shape of the first hollowed-out hole. An interval between the second hollowed-out holes adjacent to each other is smaller than an interval between the first hollowed-out holes adjacent to each other in the first direction; and/or an interval between the second hollowed-out holes adjacent to each other is smaller than an interval between the first hollowed-out holes adjacent to each other in the second direction.

In one or more exemplary embodiments of the present disclosure, the first portion and each of the at least two second portions are symmetrically disposed with respect to the bending axis. The ratio between the total area of the plurality of second hollowed-out holes and the total area of the at least two second portions is smaller than the ratio between the total area of the plurality of first hollowed-out holes and the total area of the first portion.

In one or more exemplary embodiments of the present disclosure, the plurality of second hollowed-out holes are arranged in an array, and the second hollowed-out holes adjacent to each other in the second direction are staggered. Intervals between the first hollowed-out holes adjacent to each other in the first direction are equal, and intervals between the second hollowed-out holes adjacent to each other gradually increase in a direction from the first portion to either of the at least two second portion. The interval between the first hollowed-out holes adjacent to each other in the first direction is smaller than an interval between the second hollowed-out holes adjacent to each other in the first direction.

In one or more exemplary embodiments of the present disclosure, a size of the second hollowed-out hole in the first direction gradually decreases in the first direction.

The present disclosure also provides a display device including a flexible display panel and the supporting structure as above mentioned. The flexible display panel includes a bendable region, and the supporting structure is applied to the flexible display panel.

The present disclosure further provides a manufacturing method of a supporting structure. The supporting structure is applied to a flexible display screen, the flexible display screen includes a bendable region, and a bending axis corresponding to the bendable region extends in a first direction. The manufacturing method of the supporting structure includes: providing a hollowed-out region, where an orthographic projection of the hollowed-out region on the flexible display panel completely covers a region of the flexible display panel where the bendable region is located; dividing the hollowed-out region into a first portion and at least two second portions; and performing hollowing-out process on the first portion and each of the at least two second portions to form a plurality of first hollowed-out holes on the first portion and a plurality of second hollowed-out holes on each of the at least two second portions, where the at least two second portions are at two opposite sides of the first portion in the first direction, and where a ratio between a total area of the plurality of second hollowed-out holes and a total area of the at least two second portions is different from a ratio between a total area of the plurality of first hollowed-out holes and a total area of the first portion.

The supporting structure as provided by the present disclosure can provide a certain support for the flexible display panel to improve the flatness of the flexible display panel and enhance impact resistance and bending resistance of the flexible display panel. A part of the supporting structure corresponding to the bendable region of the flexible display panel is designed as a hollowed-out region, which can facilitate bending the supporting structure to fit within a smaller bending radius while ensuring the supporting performance of the supporting structure. An orthographic projection of the hollowed-out region on the flexible display panel can completely cover the bendable region of the flexible display panel, which can enhance an ability of recovering flatness of the flexible display panel after being bent. In addition, a pattern of the first portion is different from a pattern of the second portion in the hollowed-out region, so that under the premise of ensuring the bending and deformation performance, the second portion of the hollowed-out region can be prevented from being broken, and the structural stability of the supporting structure can be ensured.

The display device as provided by the present disclosure supports the flexible display panel via the supporting structure, which can improve reliability and stability of the products.

It should be understood that the above general description and the following detailed description are merely illustrative and explanatory and should not be construed as limiting the disclosure.

### BRIEF DESCRIPTION OF THE DRAWINGS

The accompanying drawings are incorporated in and constitute one part of the specification, show the embodiments of the present disclosure, and are intended to explain the principle of the present disclosure together with the description. Understandably, the drawings as described below are only exemplary, based on which the other drawings may be obtained by the person skilled in the art without any creative effort.

FIG. 1 is a side view of a display device in which a supporting structure and a flexible display panel are assembled according to one or more embodiments of the present disclosure.

FIG. 2 is a top view of the supporting structure according to one or more embodiments of the present disclosure.

FIG. 3 is a top view of the supporting structure according to one or more embodiments of the present disclosure.

FIG. 4 is an enlarged schematic structural view of a D portion in the supporting structure shown in FIG. 3.

FIG. 5 is a schematic cross-sectional view of the supporting structure shown in FIG. 3 taken along an E-E direction.

FIG. 6 is a top view of the supporting structure according to one or more embodiments of the present disclosure.

FIG. 7 is a top view of the supporting structure according to one or more embodiments of the present disclosure.

FIG. 8 is a top view of the supporting structure according to one or more embodiments of the present disclosure.

FIG. 9 is a top view of the supporting structure according to one or more embodiments of the present disclosure.

FIG. 10 is a top view of the supporting structure according to one or more embodiments of the present disclosure.

FIG. 11 is a top view of the supporting structure according to one or more embodiments of the present disclosure.

### DETAILED DESCRIPTION

Now, the exemplary embodiments will be described more fully with reference to the accompanying drawings. However, the exemplary embodiments can be embodied in a variety of forms and should not be construed as limiting the embodiments set forth herein. Instead, these embodiments are provided so that the present disclosure will be thorough and complete, and the concepts of the exemplary embodiments will be fully given to those skilled in the art. The same reference numerals denote the same or similar structures in the drawings and thus, their detailed descriptions will be omitted.

The relative words, such as “upper” and “lower”, as used herein, are directed to describe a relative relationship between one component and another component of an icon. These words are used herein for convenience only, for example, according to the direction of the illustrative examples as shown in the figures. It should be understood that if the device is turned upside down, the component indicated as being the “upper” side would become the component on the “lower” side. When one structure is “on” another structure, it is possible to indicate that the structure is integrally formed on the other structure, or one structure is “directly” disposed on the other structure, or one structure is “indirectly” disposed on the other structure through a further structure.

The terms such as “a”, “an”, “the”, and “said” are used to indicate the presence of one or more elements/components. The terms “comprise”, “include”, “have”, “contain”, and their variants are intended to be inclusive, and mean there may be additional elements, components, etc., in addition to the listed elements, components, etc.

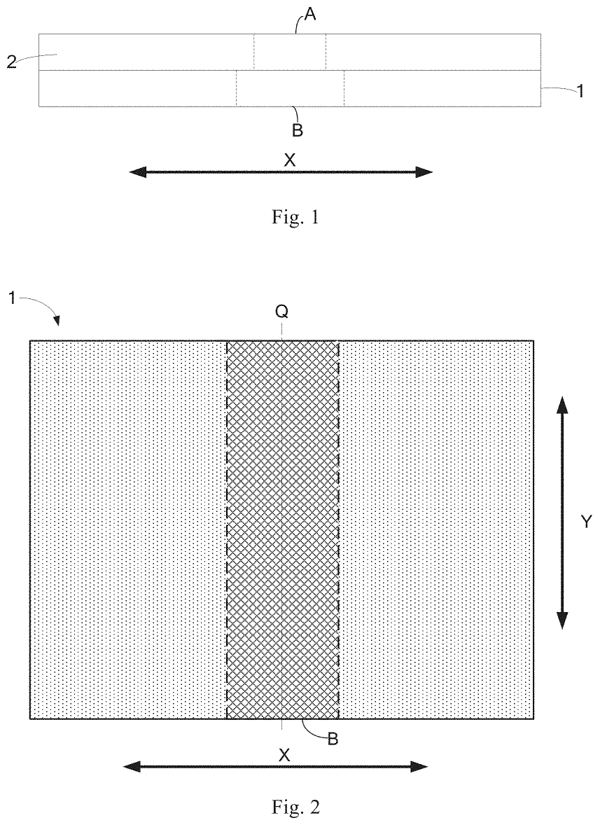

As shown in FIG. 1, one embodiment of the present disclosure provides a supporting structure 1 that can be applied to a flexible display panel 2. The flexible display panel 2 includes a bendable region A. Specifically, the supporting structure 1 may be disposed at one side of the flexible display panel 2 to provide a certain support for the flexible display panel 2, such that flatness of the flexible display panel 2 can be improved and impact resistance and bending resistance of the flexible display panel 2 can be enhanced.

As an example, the supporting structure 1 may be disposed at a back surface of the flexible display panel 2, in which the back surface refers to a surface disposed opposite to a display surface of the flexible display panel 2; however, the present disclosure is not limited thereto. The supporting structure 1 may also be disposed at the display surface of the flexible display panel 2, and at this time, the supporting structure 1 is required to be transparent to avoid affecting the normal display while providing support for the flexible display panel 2. In addition, when the supporting structure 1 is disposed at the display surface of the flexible display panel 2, the supporting structure 1 can also meet requirements of touch control.

It should be understood that, in order to satisfy supporting performance of the supporting structure 1, the supporting structure 1 may be made of materials having certain thickness and rigidity, such as metal materials; however, the present disclosure is not limited thereto.

Since the supporting structure 1 has a certain thickness and rigidity, the supporting structure 1 has a poor bending performance. Moreover, the supporting structure 1 is disadvantageous for meeting requirements of a smaller bending radius, and is not beneficial for dispersing stresses generated during bending. As such, the display performance of the flexible display panel 2 can be easily reduced.

In order to improve this situation, the technical solution adopted in this embodiment is presented, where a part corresponding to the bendable region A in the supporting structure 1 is patterned to form a hollowed-out region B having several hollowed-out holes, as shown in FIG. 1. In this way, the supporting structure 1 can stably support the flexible display panel 2, and also can improve bendability of the part of the supporting structure 1 opposite to the bendable region A of the flexible display panel 2, which facilitates meeting the requirements of a smaller bending radius. In addition, when the bendable region A of the flexible display panel 2 is bent, the hollowed-out region B can play a role of dispersing stresses to avoid damaging the flexible display panel 2 and ensure the display performance of the flexible display panel 2.

In detail, in the supporting structure 1 of this embodiment, as shown in FIG. 1, an orthographic projection of the hollowed-out region B on the flexible display panel 2 completely covers the bendable region A of the flexible display panel 2, that is, the orthographic projection of the hollowed-out region B on the flexible display panel 2 and the bendable region A of the flexible display panel 2 may completely overlap, or the bendable region A of the flexible display panel 2 is within the orthographic projection of the hollowed-out region B on the flexible display panel 2. In this way, the ability of the flexible display panel 2 to recover flatness after being bent can be enhanced.

For example, as shown in FIG. 1 and FIG. 2, a size of the hollowed-out region B may be the same as a size of the bendable region A in an extending direction Y of a bending axis Q corresponding to the bendable region A. Also, the size of the hollowed-out region B may be larger than the size of the bendable region A in a direction X orthogonal to the extending direction Y of the bending axis Q; however, the present disclosure is not limited thereto. For example, the size of the hollowed-out region B may also be equal to the size of the bendable region A.

It should be understood that the bending axis Q corresponding to the bendable region A is also a bending axis of the hollowed-out region B.

The supporting structures in different embodiments of the present disclosure will be described in detail below with reference to the accompanying drawings.

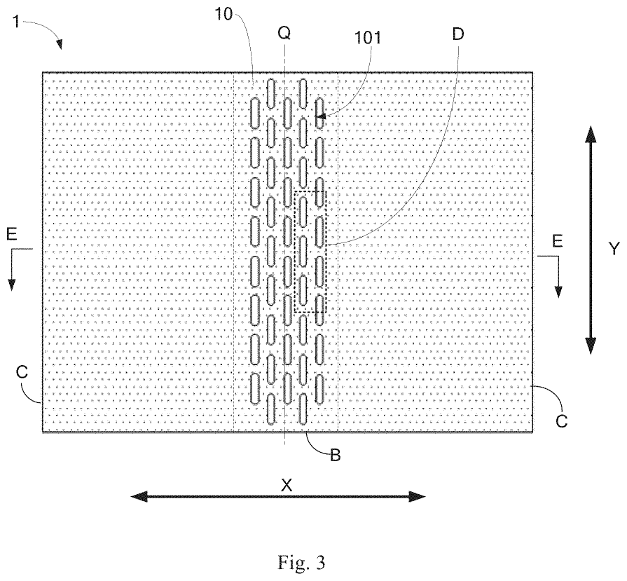

In one or more embodiments of the present disclosure, for example, as shown in FIG. 3, the hollowed-out region B of the supporting structure 1 may include a first portion 10 that also includes several hollowed-out holes, for example, a plurality of first hollowed-out holes 101 formed in the first portion 10. The first portion 10 may spread over the entire hollowed-out region B, and the orthographic projection of the first portion 10 on the flexible display panel 2 completely covers the bendable region A.

Optionally, the first portion 10 may be symmetrically disposed with respect to the bending axis Q, so that the bending axis Q has an ability to disperse stresses on both sides thereof more evenly, thereby avoiding damage to the supporting structure. For example, the first portion 10 may be rectangular, which is not limited thereto, and may also be irregularly designed depending on specific circumstances.

The plurality of first hollowed-out holes 101 may be arranged in an array in the second direction X and in the first direction Y, and the first hollowed-out holes 101 adjacent to each other in the second direction X are staggered to more uniformly disperse stresses and prevent stresses from being concentrated at a certain place during the bending process, so as to prevent damage to the supporting structure. It should be noted that, in one or more embodiments mentioned above, intervals between the first hollowed-out holes 101 adjacent to each other in the first direction Y may be equal, and intervals between the first hollowed-out holes 101 adjacent to each other in the second direction X may be equal.

Further, the first direction Y may be an extending direction of the bending axis Q, that is, the bending axis Q corresponding to the bendable region A may extend in the first direction Y, and the second direction X is orthogonal to the first direction Y.

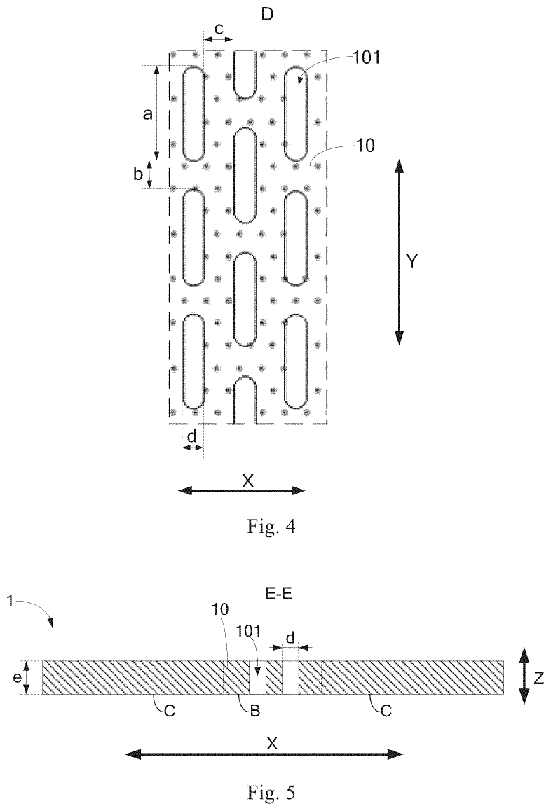

Optionally, the first hollowed-out holes 101 may be obround holes extending in the first direction Y. The obround hole refers to a hole with a rectangular central portion and semicircular end portions, specifically as shown in FIG. 4. By designing the first hollowed-out holes 101 as the obround holes, stress concentration at a single patterned boundary (i.e., a boundary of the first hollowed-out hole 101) can be reduced.

It should be understood that different bending radius can generate different stresses. In this embodiment, the pattern of the hollowed-out region B can be designed for different bending radius, so that the performance of the supporting structure 1 can meet bending requirements, and situations in which the supporting structure 1 is damaged during the bending process or the supporting structure 1 is not able to provide good support for the flexible display panel 2 can be avoided.

Specifically, as shown in FIG. 4, as designing the pattern of the first portion 10, a relationship between its parameters and the bending radius of the supporting structure 1 is presented as follows:

$$\frac{{c}^{3}}{{a}^{3}} < 4.5 \times r ;$$

where “a” is the size of the first hollowed-out hole 101 in the first direction Y; “c” is an interval between the first hollowed-out holes 101 adjacent to each other in the second direction X; and “r” is a bending radius corresponding to the supporting structure 1.

As shown in FIG. 4 and FIG. 5, parameters in the pattern of the first portion 10 should be satisfied for the following relationships:

a ratio between “a” and “b” is 10 to 100;

a ratio between “b” and “c” is 0.5 to 4;

a ratio between “d” and “c” is 1 to 5; and

a ratio between “e” and “c” is 1 to 4,

where “a” is the size of the first hollowed-out hole 101 in the first direction Y; “b” is an interval between the first hollowed-out holes 101 adjacent to each other in the first direction Y; “c” is an interval between the first hollowed-out holes 101 adjacent to each other in the second direction X; “d” is the size of the first hollowed-out hole 101 in the second direction X; and “e” is the size of the first hollowed-out hole 101 in its own axial direction Z, as shown in FIG. 5. That is, “e” is a thickness of the supporting structure 1 at the first portion 10.

It should be noted that shape and arrangement of the first hollowed-out holes 101 in the first portion 10 are not limited to any forms described above, and may be determined depending on the specific circumstances.

Optionally, the supporting structure 1 of this embodiment may include not only the hollowed-out region B, but also non-hollowed-out regions C corresponding to non-bendable regions in the flexible display panel 2. In addition, non-hollowed-out regions C may be located on two opposite sides of the hollowed-out region B in the second direction X, so that the supporting structure 1 can support the flexible display panel 2 stably.

In one or more embodiments of the present disclosure, the first portion 10 does not spread over the entire hollowed-out region B, and this design is different from the embodiments shown in FIGS. 3-5; but other design concepts may be the same as that of the embodiments shown in FIGS. 3-5, the present disclosure is not limited thereto, and also may be different depending on the specific circumstances.

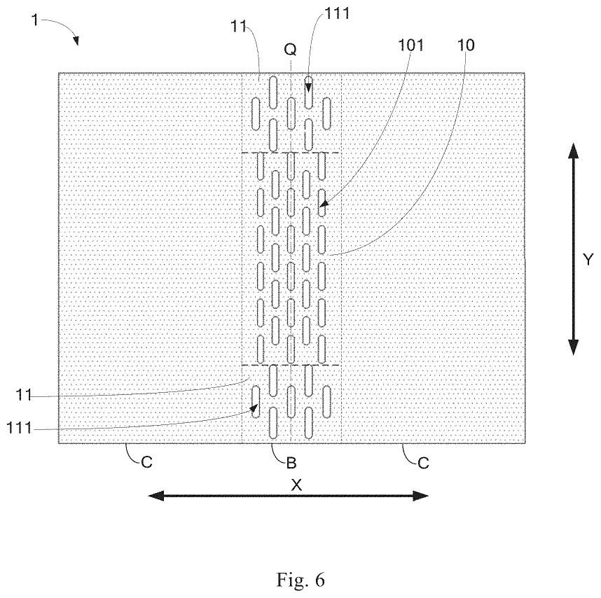

Specifically, as shown in FIG. 6 to FIG. 8, the first portion 10 may be located at a middle position of the hollowed-out region B, for example, at a middle position of the hollowed-out region B along an up and down direction the figures. The hollowed-out region B may further include second portions 11 located at opposite sides of the first portion 10 in the first direction Y, that is, the second portion 11 is located at an edge position of the hollowed-out region B.

For example, the first portion 10 and the second portions 11 are both symmetrically disposed with respect to the bending axis Q, so that the bending axis Q has the ability to disperse stresses on both sides more evenly to prevent the supporting structure 1 from being damaged.

Specifically, the first portion 10 and the second portion 11 may be rectangular, and the size of the first portion 10 and the sizes of the second portions 11 in the second direction X are equal, that is, the hollowed-out region B entirely may be rectangular. In this way, difficulty of designing the hollowed-out region may be reduced. It should be understood that, when the hollowed-out region is rectangular, a boundary between the hollowed-out region and the non-hollowed-out region is a straight line.

In addition, several hollowed-out holes include not only a plurality of first hollowed-out holes 101 formed in the first portion 10, but also a plurality of second hollowed-out holes 111 formed in the second portion 11, as shown in FIGS. 6 to 8.

It should be understood that, in this embodiment, the shape, the area, and the arrangement of the first hollowed-out holes 101 in the first portion 10 may refer to those of the first hollowed-out holes 101 in the first portion 10 in the first embodiment shown in FIG. 3 and FIG. 4, which will not be described further herein.

The plurality of second hollowed-out holes 111 in the second portion 11 may be arranged in an array in the second direction X and in the first direction Y, and the second hollowed-out holes 111 adjacent to each other in the second direction X may be staggered to better disperse stress and avoid stress from being concentrated in a certain place during the bending process, so as to prevent the supporting structure 1 from being damaged. It should be noted that, in this embodiment, intervals between the second hollowed-out holes adjacent to each other 111 in the first direction Y may be equal, and intervals between the second hollowed-out holes adjacent to each other 111 in the second direction X may be equal.

The shape and the arrangement of the second hollowed-out holes 111 in the second portion 11 are not limited to those described above, and may be determined depending on the specific circumstances.

During the bending process of the supporting structure 1 along with the flexible display panel 2, the hollowed-out region B can be unavoidably deformed, and stresses endured at different positions of the hollowed-out region B are different. It can be found from simulation that the stresses endured at edge areas are larger than the stresses endured at the middle area, so that the edge areas are prone to fracture. Therefore, with regard to the problem of uneven stresses at the hollowed-out region B, as designing the hollowed-out region B, a ratio between a total area of the plurality of second hollowed-out holes 111 and a total area of the second portions 11 may be designed to be greater than a ratio between a total area of the plurality of first hollowed-out hole 101 and a total area of the first portion 10, that is, an occupied area of openings on the second portion 11 is increased, so that under the premise of ensuring the bending deformation performance, the ability of the second portion to disperse stress can be improved, and the fracture of the second portion 11 of the hollowed-out region B can be avoided.

In order to enable the ratio between the total area of the plurality of second hollowed-out holes 111 and the total area of the second portions 11 to be greater than the ratio between the total area of the plurality of first hollowed-out holes 101 and the total area of the first portion 10, this embodiment may be specifically designed according to the following aspects.

Optionally, the area of second hollowed-out holes 111 is increased, so that the occupied area of the openings on the second portion 11 is larger than the occupied area of the openings on the first portion 10. In the second direction X, the interval between the second hollowed-out holes adjacent to each other 111 is equal to the interval between the first hollowed-out holes 101 adjacent to each other; and in the first direction Y, the interval between the second hollowed-out holes adjacent to each other 111 is equal to the interval between the first hollowed-out holes 101 adjacent to each other.

In one optional example, as shown in FIG. 6, the second hollowed-out holes 111 are obround holes extending in the first direction Y, that is to say, the shape of the second hollowed-out hole 111 may be the same as that of the first hollowed-out hole 101. However, the size of the second hollowed-out hole 111 in the first direction Y is larger than the size of the first hollowed-out hole 101 in the first direction Y; and/or the size of the second hollowed-out hole 111 in the second direction X is larger than the size of the first hollowed-out hole 101 in the second direction X. In this way, the ability of the second portion 11 to disperse stress can be improved, and the difficulty of patterning the entire hollowed-out region can be reduced.

It should be understood that, in this example, the shape of the second hollowed-out hole 111 or the shape of the first hollowed-out hole 101 are not limited to the obround shape, and may be other shapes.

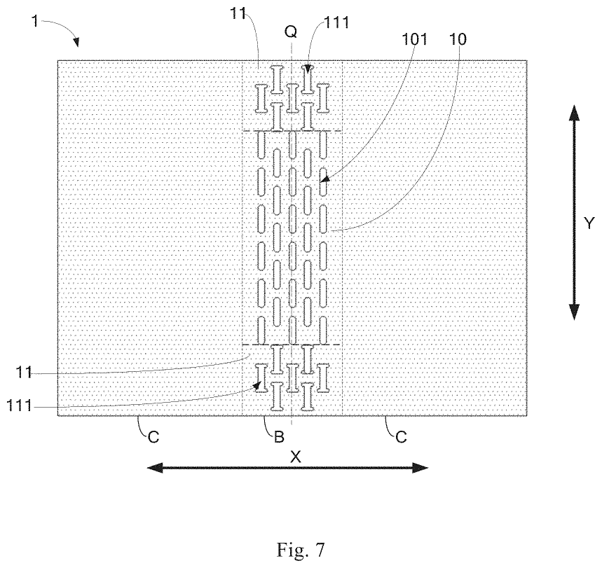

In another optional example, as shown in FIG. 7, the shape of the second hollowed-out hole 111 is different from the shape of the first hollowed-out hole 101. For example, the first hollowed-out hole 101 has a first body portion and first end portions, and the first end portions are located at opposite sides of the first body portion in the first direction Y; the second hollowed-out hole 111 has a second body portion and second end portions, and the second end portions are located at opposite sides of the second body portion in the first direction Y. The area and the shape of the first body portion may be the same as the area and the shape of the second body portion, and optionally, both the first body portion and the second body portion are rectangular. The shape of the first end portion is different from the shape of the second end portion, and the area of the second end portions is larger than the area of the first end portions. Optionally, the first end portion is semicircular and the second end portion may be a circle, an ellipse, a triangle, or an obround extending in the second direction X. In this way, the stress concentration at the end portions of the second hollowed-out holes 111 can be reduced, and the fracture of the second portion 11 can be avoided. It should be understood that, the shape of the second hollowed-out hole 111 and the shape of the first hollowed-out hole 101 are not limited to the shapes described above, and may be other shapes.

Optionally, the interval between the second hollowed-out holes adjacent to each other 111 is reduced, so that the occupied area of the openings on the second portion 11 is larger than the occupied area of the openings on the first portion 10; and the area and the shape of the second hollowed-out holes 111 may be the same as the area and the shape of the first hollowed-out holes 101.

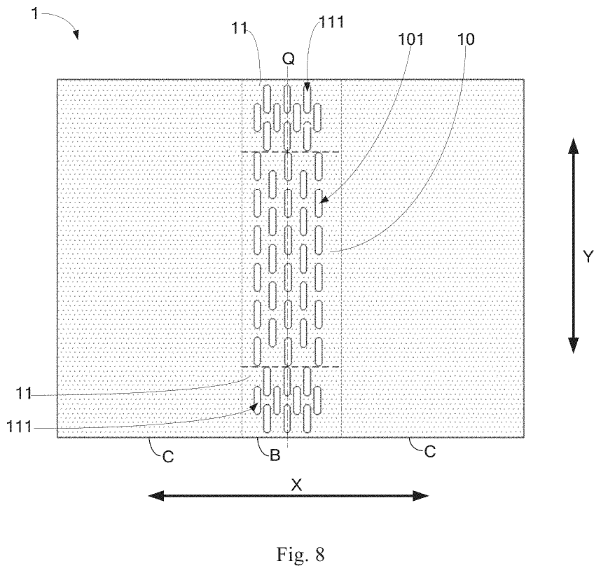

Specifically, as shown in FIG. 8, in the first direction Y, the interval between the second hollowed-out holes adjacent to each other 111 is smaller than the interval between the first hollowed-out holes 101 adjacent to each other; and/or in a second direction X, the interval between the second hollowed-out holes adjacent to each other 111 is smaller than the interval between the first hollowed-out holes 101 adjacent to each other. In this way, the ability of the second portion 11 to disperse stresses can be improved, and the difficulty of patterning the entire hollowed-out region can be reduced.

Optionally, the area of the second hollowed-out holes 111 is increased, and at the same time, the interval between the second hollowed-out holes adjacent to each other 111 is reduced, such that the ability of the second portion 11 to disperse stresses can be improved. That is, the example shown in FIGS. 6-7 and the example shown in FIG. 8 can be combined, and details will not be repeated herein.

In one or more embodiments of the present disclosure, in order to avoid the edge region of the hollowed-out region B from being easily broken, as designing the hollowed-out region B, the ratio between the total area of the second hollowed-out holes 111 and the total area of the second portion 11 is designed to be smaller than the ratio between the total area of the plurality of first hollowed-out holes 101 and the total area of the first portion 10, so that rigidity of the second portion 11 can be increased, and thus damage-resist ability of the second portion 11 can be improved. Other design concepts may be the same as those of the embodiments shown in FIGS. 6-8, which will not be repeated herein, but the present disclosure is not limited thereto, and the other design concepts may be different from those of the second embodiment depending on the specific circumstances.

In this embodiment, in order to enable the ratio between the total area of the second hollowed-out holes 111 and the total area of the second portion 11 to be smaller than the ratio between the total area of the plurality of first hollowed-out holes 101 and the total area of the first portion 10, it can be implemented by reducing the area of the first hollowed-out holes 101 and/or increasing the interval between the second hollowed-out holes adjacent to each other 111, to reduce the occupied area of the openings on the second portion 11, so as to increase the damage-resist ability of the second portion 11 and increase structural strength of the second portion 11.

In order to avoid rigidity difference between the first portion 10 and the second portions 11, and thus reduce the stress concentration due to the rigidity difference, this embodiment can be designed as follows.

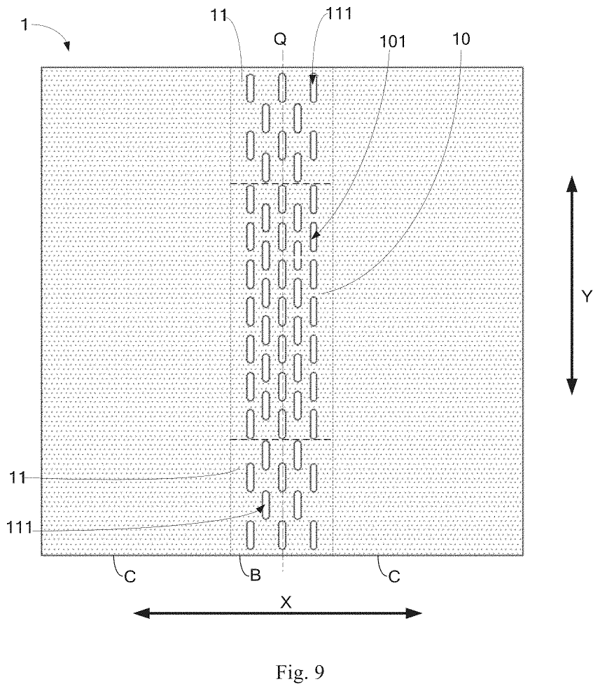

As shown in FIG. 9, the interval between the second hollowed-out holes adjacent to each other 111 gradually increases in a direction from the first portion 10 to the second portion 11; and the interval between the first hollowed-out holes 101 adjacent to each other in the first direction Y is smaller than the interval between the second hollowed-out holes adjacent to each other 111 in the first direction Y.

It should be noted that, the intervals between the first hollowed-out holes 101 adjacent to each other in the first direction Y are equal. However, the present disclosure is not limited thereto, that is, the intervals between the first hollowed-out holes 101 adjacent to each other in the first direction Y may also be unequal. For example, the interval between the first hollowed-out holes 101 adjacent to each other increases in a direction from a center of the first portion 10 to the second portions 11.

It should be understood that when the intervals between the first hollowed-out holes 101 adjacent to each other in the first direction Y are unequal, in this embodiment, the interval between the second hollowed-out holes adjacent to each other 111 in the first direction Y should be larger than a maximum interval between holes on the first portion 10 in the first direction.

Further, the size of the second hollowed-out hole 111 in the first direction Y is gradually reduced in the first direction Y to further reduce the occupied area of the openings of the second portion 11, such that the damage-resist ability of the second portion 11 can be increased and the structural strength of the second portions 11 can be improved.

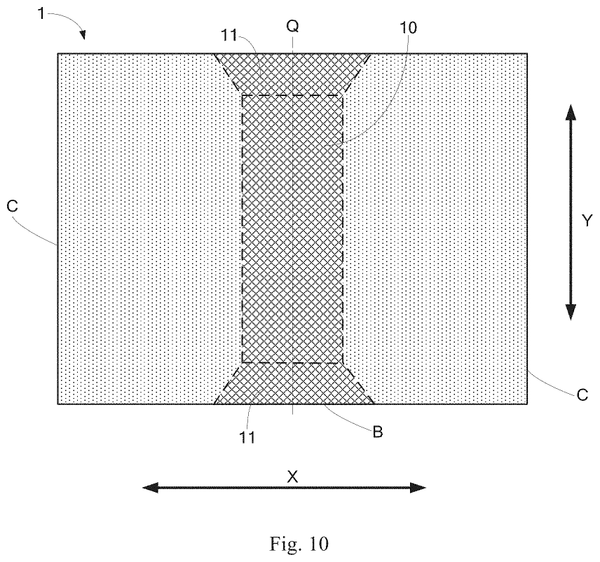

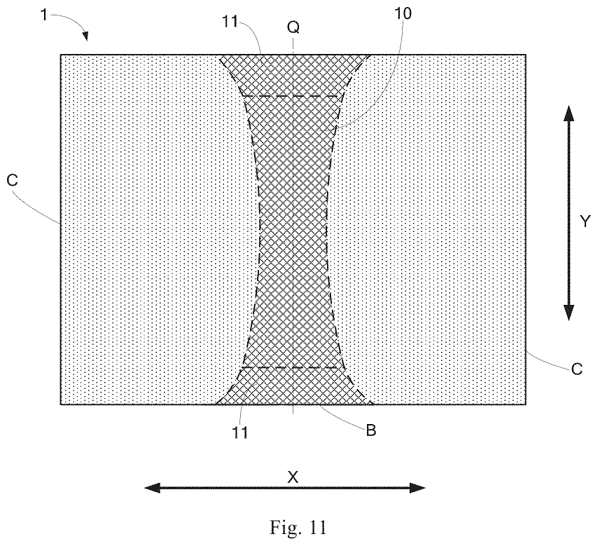

In one or more embodiments of the present disclosure, in order to avoid a risk of stress concentration at a junction between the non-hollowed-out region C and the hollowed-out region B during the bending process, the junction between the hollowed-out region B and the non-hollowed-out region C is designed to be non-linear, as shown in FIGS. 10 and 11. Other design concepts may be the same as those of the embodiment shown in FIGS. 6-8, which will not be repeated herein, but, the present disclosure is not limited thereto, and the other design concepts may be different from those of the embodiment shown in FIGS. 6-8 depending on the specific circumstances.

In this embodiment, since the non-hollowed-out region C is not patterned, the rigidity of the non-hollowed-out region C is greater than the rigidity of the hollowed-out region B, so that the risk of the stress concentration may easily occur at the junction between the non-hollowed-out region C and the hollowed-out region B during the bending process, resulting in a situation that the supporting structure 1 is damaged. In order to improve this situation, the junction between the hollowed-out region B and the non-hollowed-out region C is designed to be non-linear. On the premise of ensuring the bending deformation performance, it is also possible to improve the stability of the supporting structure 1 while avoiding the risk of the stress concentration at the junction between the non-hollowed-out region C and the hollowed-out region B during the bending process.

Specifically, the hollowed-out region in this embodiment may be designed according to the following aspects.

Optionally, as shown in FIG. 10, in the direction from the center of the first portion 10 to the second portions 11, the size of the first portion 10 in the second direction X is unchanged, and the first portion 10 may be rectangular. In the direction from the center of the first portion 10 to the second portions 11, the size of the second portion 11 in the second direction X gradually increases, and the second portion 11 may be trapezoidal, but the present disclosure is not limited thereto, and may also be other shapes. The minimum size of the second portion 11 in the second direction X is greater than or equal to the size of the first portion 10 in the second direction X.

Optionally, as shown in FIG. 11, the size of the first portion 10 in the second direction X gradually increases in the direction from the center of the first portion 10 to the second portions 11, for example, an edge of the first portion 10 in contact with the non-hollowed-out region C is arc-shaped, but the present disclosure will not be limited thereto. The size of the second portion 11 in the second direction X gradually increases in the direction from the center of the first portion 10 to the second portions 11, for example, an edge of the second portion 11 in contact with the non-hollowed-out region C is arc-shaped, and the edges of the second portions 11 in contact with the non-hollowed-out region C and the edge of the first portion 10 in contact with the non-hollowed-out region C may be in smooth transitions, but the present disclosure will not be limited thereto. The minimum size of the second portions 11 in the second direction X is greater than or equal to the maximum size of the first portion 10 in the second direction X.

One embodiment of the present disclosure further provides a display device. As shown in FIG. 1, the display device includes a flexible display panel 2 and the supporting structure 1 as described in any of the foregoing embodiments. The flexible display panel 2 includes a bendable region A, and also includes a non-bendable region except for the position of the bendable region A. The supporting structure 1 may be disposed at one side of the flexible display panel 2, and a relationship between the supporting structure 1 and the flexible display panel 2 may specifically refer to the description in any one of the foregoing embodiments, which will not be described further herein.

For example, the flexible display panel 2 may be an OLED (Organic Light-Emitting Diode) display panel, but the present disclosure will not be limited thereto, and may also be a liquid crystal display panel.

The specific type of the display device is not particularly limited, and any type of display devices commonly used in the art, for example, mobile devices having a display device, such as one or more liquid crystal displays, OLED displays, mobile phones, wearable devices such as watches, VR devices, etc. that may be available. Those skilled in the art can make a corresponding selection according to specific use requirements of the display device, which will not be repeated herein.

It should be noted that, in addition to the flexible display panel 2 and the supporting structure 1, the display device also includes other necessary components and parts, for example, a displayer, including a housing, a circuit board, and power cables. Those skilled in the art can make corresponding supplement according to the specific use requirements of the display device, which will not be repeated herein.

The present disclosure further provides a manufacturing method of a supporting structure 1. The supporting structure 1 is applied to a flexible display screen 2, the flexible display screen 2 includes a bendable region A, and a bending axis corresponding to the bendable region A extends in a first direction, The manufacturing method of the supporting structure 1 includes: providing a hollowed-out region B, wherein an orthographic projection of the hollowed-out region B on the flexible display panel 2 completely covers a region of the flexible display panel 2 where the bendable region A is located; and dividing the hollowed-out region B into a first portion 10 and at least two second portions 11, performing hollowing-out process on the first portion 10 and each of the at least two second portions 11 to form a plurality of first hollowed-out holes 101 on the first portion 10 and a plurality of second hollowed-out holes 111 on each of the at least two second portions 11, wherein the at least two second portions 11 are at two opposite sides of the first portion 10 in the first direction, and wherein a ratio between a total area of the plurality of second hollowed-out holes 111 and a total area of the at least two second portions 11 is different from a ratio between a total area of the plurality of first hollowed-out holes 101 and a total area of the first portion 10.

Other embodiments of the present disclosure will be apparent to those skilled in the art for consideration of the specification and practice of the disclosure herein, or the embodiments mentioned in this application can also be combined. The present disclosure is intended to cover any variations, uses, or adaptations of the present disclosure following the general principles thereof and including such departures from the present disclosure as come within known or customary practice in the art. The specification and embodiments are to be regarded as illustrative only, with a real scope and spirit of the present disclosure being indicated by following appended claims.

What is claimed is:

1. A supporting structure applied to a flexible display panel, the flexible display panel having a bendable region and a bending axis corresponding to the bendable region extending in a first direction, wherein:
the supporting structure comprises a hollowed-out region, an orthographic projection of the hollowed-out region on the flexible display panel completely covering a region of the flexible display panel where the bendable region is located;
the hollowed-out region comprises:
a first portion, wherein the first portion has a plurality of first hollowed-out holes; and
at least two second portions, wherein the at least two second portions at two opposite sides of the first portion in the first direction, and each of the at least two second portions has a plurality of second hollowed-out holes; and
a ratio between a total area of the plurality of second hollowed-out holes and a total area of the at least two second portions is different from a ratio between a total area of the plurality of first hollowed-out holes and a total area of the first portion.

2. The supporting structure according to claim 1, wherein:
the first hollowed-out holes are obround holes extending in the first direction;
the plurality of first hollowed-out holes are arranged in an array; and
the first hollowed-out holes adjacent to each other in a second direction are staggered, the second direction being orthogonal to the first direction.

3. The supporting structure according to claim 2, wherein:
a size of the first hollowed-out hole in the first direction is A;
an interval between the first hollowed-out holes adjacent to each other in the second direction is C; and
a bending radius corresponding to the supporting structure is R,
wherein
$$\frac{{C}^{3}}{{A}^{3}} < 4.5 \times R .$$

4. The supporting structure according to claim 3, wherein:
an interval between the first hollowed-out holes adjacent to each other in the first direction is B;
a size of the first hollowed-out hole in the second direction is D; and
a size of the first hollowed-out hole in its axial direction is E; and
a ratio between A and B is 10 to 100, a ratio between B and C is 0.5 to 4, a ratio between D and C is 1 to 5, and a ratio between E and C is 1 to 4.

5. The supporting structure according to claim 2, wherein:
the first portion and each of the at least two second portions are symmetrically disposed with respect to the bending axis; and
the ratio between the total area of the plurality of second hollowed-out holes and the total area of the at least two second portions is greater than the ratio between the total area of the plurality of first hollowed-out holes and the total area of the first portion.

6. The supporting structure according to claim 5, wherein:
in a direction from a center of the first portion to either of the at least two second portions, a size of the first portion in the second direction is unchanged, and a size of either of the at least two second portions in the second direction gradually increases; and
a minimum size of either of the at least two second portions in the second direction is greater than or equal to the size of the first portion in the second direction.

7. The supporting structure according to claim 5, wherein:
in a direction from the center of the first portion to either of the at least two second portions, a size of the first portion in the second direction gradually increases, and a size of either of the at least second portions in the second direction gradually increases; and
a minimum size of either of the at least two second portions in the second direction is greater than or equal to a maximum size of the first portion in the second direction.

8. The supporting structure according to claim 5, wherein an area of the second hollowed-out holes is larger than an area of the first hollowed-out holes.

9. The supporting structure according to claim 8, wherein the second hollowed-out holes are obround holes extending in the first direction, the plurality of second hollowed-out holes are arranged in an array, and second hollowed-out holes adjacent to each other in the second direction are staggered; and
wherein a size of the second hollowed-out hole in the first direction is larger than a size of the first hollowed-out hole in the first direction, or a size of the second hollowed-out hole in the second direction is larger than a size of the first hollowed-out hole in the second direction.

10. The supporting structure according to claim 8, wherein:
the first hollowed-out hole has a first body portion and first end portions located at opposite sides of the first body portion in the first direction;
the second hollowed-out hole has a second body portion and second end portions located at opposite sides of the second body portion in the first direction;
an area and a shape of the first body portion are identical to an area and a shape of the second body portion; and
a shape of the first end portion is different from a shape of the second end portion, and an area of the second end portion is larger than an area of the first end portion.

11. The supporting structure according to claim 5, wherein an area and a shape of the second hollowed-out hole are identical to an area and a shape of the first hollowed-out hole; and
wherein an interval between the second hollowed-out holes adjacent to each other is smaller than an interval between the first hollowed-out holes adjacent to each other in the first direction, or an interval between the second hollowed-out holes adjacent to each other is smaller than an interval between the first hollowed-out holes adjacent to each other in the second direction.

12. The supporting structure according to claim 2, wherein:
the first portion and each of the at least two second portions are symmetrically disposed with respect to the bending axis; and
the ratio between the total area of the plurality of second hollowed-out holes and the total area of the at least two second portions is smaller than the ratio between the total area of the plurality of first hollowed-out holes and the total area of the first portion.

13. The supporting structure according to claim 12, wherein:
the plurality of second hollowed-out holes are arranged in an array, and the second hollowed-out holes adjacent to each other in the second direction are staggered;
intervals between the first hollowed-out holes adjacent to each other in the first direction are equal;
intervals between the second hollowed-out holes adjacent to each other gradually increase in a direction from the first portion to either of the at least two second portions; and
the interval between the first hollowed-out holes adjacent to each other in the first direction is smaller than an interval between the second hollowed-out holes adjacent to each other in the first direction.

14. The supporting structure according to claim 13, wherein, in the first direction, a size of the second hollowed-out hole in the first direction gradually decreases.

15. A display device, comprising:
a flexible display panel having a bendable region and a bending axis corresponding to the bendable region extending in a first direction;
a supporting structure applied to the flexible display panel, comprising:
a hollowed-out region, an orthographic projection of the hollowed-out region on the flexible display panel completely covering a region of the flexible display panel where the bendable region is located, the hollowed-out region comprising:
a first portion having a plurality of first hollowed-out holes; and
at least two second portions, wherein the at least two second portions at two opposite sides of the first portion in the first direction, and each of the at least two second portions has a plurality of second hollowed-out holes; and
wherein a ratio between a total area of the plurality of second hollowed-out holes and a total area of the at least two second portions is different from a ratio between a total area of the plurality of first hollowed-out holes and a total area of the first portion.
wherein the flexible display panel comprises a bendable region, and the supporting structure is applied to the flexible display panel.

16. A manufacturing method of a supporting structure, the supporting structure being applied to a flexible display screen, the flexible display screen having a bendable region, and a bending axis corresponding to the bendable region extending in a first direction, wherein the manufacturing method of the supporting structure comprises:
providing a hollowed-out region, wherein an orthographic projection of the hollowed-out region on the flexible display panel completely covers a region of the flexible display panel where the bendable region is located; and
dividing the hollowed-out region into a first portion and at least two second portions, performing hollowing-out process on the first portion and each of the at least two second portions to form a plurality of first hollowed-out holes on the first portion and a plurality of second hollowed-out holes on each of the at least two second portions;
wherein the at least two second portions are at two opposite sides of the first portion in the first direction; and
wherein a ratio between a total area of the plurality of second hollowed-out holes and a total area of the at least two second portions is different from a ratio between a total area of the plurality of first hollowed-out holes and a total area of the first portion.
